(19) United States
(12) Patent Application Publication
(10) Pub. No.: US 2025/0006667 A1
(43) Pub. Date: Jan. 2, 2025

(54) AMPLIFIER AND MIXER IN A III-V MATERIAL FOR WIDEBAND SUB-TERAHERTZ COMMUNICATION

(71) Applicant: Intel Corporation, Santa Clara, CA (US)

(72) Inventors: Georgios PANAGOPOULOS, Munich (DE); Steven CALLENDER, Denver, CO (US); Richard GEIGER, Munich (DE); Georgios C. DOGIAMIS, Chandler, AZ (US); Manisha DUTTA, Munich (DE); Stefano PELLERANO, Beaverton, OR (US)

(21) Appl. No.: 18/341,916

(22) Filed: Jun. 27, 2023

(51) Int. Cl. H01L 23/66; H01L 29/16; H01L 29/20; H03F 3/195; H03F 3/213

(52) U.S. Cl. CPC H01L 23/66; H01L 29/16; H01L 29/20; H03F 3/195; H03F 3/213; H01L 2223/6644; H01L 2223/6677; H03F 2200/294

(57) ABSTRACT

Embodiments herein relate to systems, apparatuses, or processes directed to a package for wideband sub-terahertz communication, where the package includes a mixer and an amplifier, such as a power amplifier or a low noise amplifier, that are implemented within a layer of III-V material. Other embodiments may be described and/or claimed.

### FIELD

Embodiments of the present disclosure generally relate to the field of package assemblies, and in particular package assemblies that include wideband communication circuitry.

### BACKGROUND

Continued reduction in end-product size of mobile electronic devices such as smart phones and ultrabooks is a driving force for the development of integrated circuit packages that include wideband wireless communication.

### BRIEF DESCRIPTION OF THE DRAWINGS

FIG. 1 illustrates a cross-section side view of a legacy implementation of a silicon-based package that includes wideband components.

FIGS. 2A-2B illustrate a cross section side view of examples of a sub-terahertz wideband communication package that includes baseband components in a silicon layer and amplifier and mixer components in a III-V layer, in accordance with various embodiments.

FIG. 3 illustrates a cross-section side view of an example of a sub-terahertz wideband communication package that includes a controller in a silicon layer that is coupled with one or more wideband communication components in a III-V layer on the silicon layer, in accordance with various embodiments.

FIG. 4 illustrates a cross-section side view of an example of a sub-terahertz wideband communication package that includes two chips that include a III-V layer on a silicon layer, where one chip is a transmitter and the other chip is a receiver, in accordance with various embodiments.

FIG. 5 illustrates a cross-section side view of an example of a sub-terahertz wideband communication package that includes a chip that includes a III-V layer that includes a transmitter that is on a silicon layer that includes a receiver, in accordance with various embodiments.

FIG. 6 illustrates a top-down view of an example of a silicon layer with various chips on the silicon layer that include a III-V layer with sub-terahertz wideband communication components, in accordance with various embodiments.

FIGS. 7A-7B illustrate top-down views and cross-section side views of wired and wireless communications between a chip that includes a III-V layer of a sub-terahertz wideband communication package and an antenna, in accordance with various embodiments.

FIG. 8 illustrates an example of a process for manufacturing a sub-terahertz wideband communication package that is at least partially formed within a III-V layer, in accordance with various embodiments.

FIG. 9 schematically illustrates a computing device, in accordance with embodiments.

### DETAILED DESCRIPTION

Embodiments of the present disclosure may generally relate to systems, apparatus, and/or processes directed to a package for wideband sub-terahertz, or greater than 100 GHz, communication, where the package includes a mixer and an amplifier, such as a power amplifier or a low noise amplifier, that are implemented within a layer of III-V material. In embodiments, the layer of III-V material may be within a chip or a die. In embodiments, the layer of III-V material may be on a silicon layer, or a CMOS layer, that includes other components that support wideband sub-terahertz communication, for example baseband receiving and/or baseband transmitting circuitry.

In embodiments described herein, the local oscillator (LO) distribution path may be split between the silicon layer and the layer of III-V material. In embodiments, such a split may facilitate the generation of high-performance phase-loop lock (PLL) and low-to-medium-frequency multipliers, which herein may be referred to as multipliers, within a silicon domain, while eliminating the need for wideband radio frequency (RF) routing between a silicon layer and a layer of III-V material.

In embodiments, the layer of III-V material may also include an IQ phase generator, for example a quadrature hybrid, that may be coupled with the mixer and/or a multiplier. In other embodiments, portions of a multiplier may exist in the layer of III-V material and in the silicon layer. In other embodiments, other components, for example controllers, data converters, equalizers, power management circuitry, digital processing circuitry, and/or memory subsystems, may be fabricated within the silicon layer and be electrically coupled with the various components within the layer of III-V material, such as the amplifier, mixer, IQ phase generator, and/or multiplier. In embodiments, a PLL may be at least partially implemented within the silicon layer, and coupled with one or more multipliers that may be within the layer of III-V material.

In embodiments, the location of the various components either in the layer of III-V material or the silicon layer may be selected based upon process capabilities of the III-V layer and silicon layer, such as unity current gain frequency (ft), unity power gain frequency (fmax), transistor density, and digital performance, all of which impact system-level performance requirements. In embodiments, the location of the various components may be separated within the local oscillator (LO) distribution path. In other embodiments, the location of the various components may be separated at the output/input of a baseband signal path that may be within the silicon layer, and may be just before the input/output of the mixer, which may be in the layer of III-V material.

In embodiments, with respect to the LO distribution path, LO multiplication may be distributed by using multipliers implemented within the silicon layer coupled with multipliers implemented within a layer of III-V material. As a result, this may facilitate a single phase LO frequency to be routed at a fraction of the carrier across a silicon/III-V boundary. In embodiments, passive IQ generation may be performed locally to the mixer within the III-V layer. In embodiments, all of the sub-terahertz range circuitry may be implemented within the III-V layer for improved gain, noise, output power capacity and power efficiency. In embodiments, all or part of the baseband circuitry may be implemented within the silicon layer, where higher integration and scaling may be achieved.

In embodiments, by implementing portions of the package for wideband sub-terahertz communication at least partially in a layer of III-V material, bandwidth enhancements may be achieved in comparison with legacy implementations. In addition, there may be improved power efficiency by implementing sub terahertz blocks, including portions of LO generation, in III-V material. In addition, there may be more flexibility in positioning the III-V layer with respect to the silicon layer, such that there may be lower frequency and/or lower bandwidth interfaces between the silicon layer and the layer of III-V material, and therefore higher losses may be tolerated. Also, embodiments may provide a more scalable architecture as compared to legacy implementations.

In these systems, scalability is usually limited by issues with LO distribution. Higher frequency LO cannot be easily distributed across many elements. By having a lower frequency and single phase LO generated in the silicon layer, this same LO can more readily fan-out and source LO input of many front-end elements implemented in the III-V layer.

In legacy implementations, only a radiofrequency (RF) signal may be passed between a silicon layer and a layer of III-V material. However, in embodiments described herein, multiple signals, for example but not limited to single phase local oscillators and baseband signals, may be routed between the silicon layer and the layer of III-V material. In these legacy implementations, delivering wideband modulated signals between chips required wideband through silicon vias (TSV) or wideband connections in general. In legacy implementations, wire bond assemblies are used between silicon layers and layers of III-V material, which may provide limited bandwidth performance in addition to high-sensitivity to wire bond length, which may pose a challenge for assembly tolerances. In addition, these legacy connections may incur higher losses and become more difficult to optimize as frequency of operations increases.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

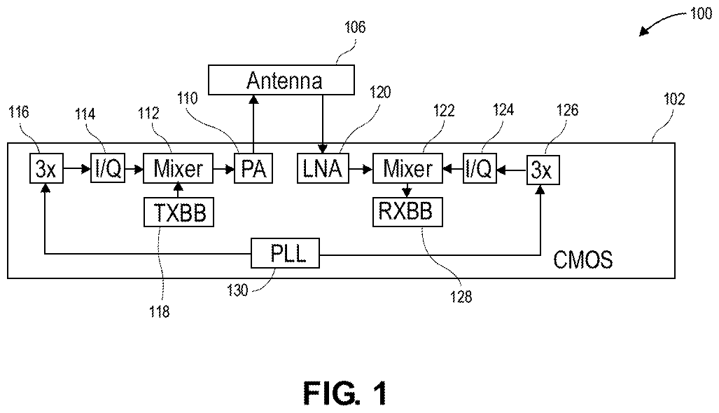

FIG. 1 illustrates a cross-section side view of a legacy implementation of a silicon-based package that includes wideband components. Package 100, which may also be referred to as transceiver, includes a silicon layer 102 that is communicatively coupled with an antenna structure 106. In embodiments, the silicon layer 102 may be a chip or a die. In implementations, the silicon layer 102 includes a power amplifier 110 that may be communicatively coupled with the antenna structure 106, and a first mixer 112 that may be coupled with the power amplifier 110.

A first IQ phase generator 114 may be within the silicon layer 102 and may be communicatively coupled with the first mixer 112. A first multiplier 116 may be communicatively coupled with the first IQ phase generator 114. In implementations, transmission baseband circuitry (TXBB) 118 may be communicatively coupled with the first mixer 112. The power amplifier 110, first mixer 112, first IQ phase generator 114, the first multiplier 116, and the TXBB 118 may be a portion of the transmitter circuitry within the silicon layer 102.

The silicon layer 102 may include a low noise amplifier 120 that may be communicatively coupled with the antenna structure 106. A second mixer 122 may be coupled with low noise amplifier 120. A second IQ phase generator 124 may be coupled with the second mixer 122, and a second multiplier 126 may be coupled with the second IQ phase generator 124. In implementations, reception baseband circuitry (RXBB) 128 may be communicatively coupled with the second mixer 122. A PLL 130 may be coupled with the first multiplier 116 and the second multiplier 126.

In these legacy implementations, where the silicon layer 102 may represent a monolithic system-on-chip solution. In these implementations, where co-integration of both high-frequency front end blocks, for example, the mixers 112, 122, the power amplifier 110, and the low noise amplifier 120, may not adequately support high performance baseband and digital processing, for example for communications at the sub-terahertz range. In addition, performance, area requirements, and power efficiency of high-frequency blocks may be limited when implemented within CMOS technology.

In some legacy implementations, a III-V layer (not shown) may exist between the silicon layer 102 and the antenna structure 106 in order to amplify and drive a wideband modulated sub-terahertz carrier off of the silicon layer 102. As a result, these legacy implementations involve routing wideband modulated signals off chip, and also require wideband interfaces between the silicon layer 102 (which may be referred to as the CMOS layer) and the layer of III-V components. However, these legacy implementations may be expensive and power inefficient due to losses and bandwidth reduction in the off chip routing.

Legacy implementations that use a combination approach, combining both a silicon layer 102 with a layer of III-V material (not shown) to build a sub-terahertz transceiver chain, locate the mixers 112, 122 and/or the power amplifier 110 and the low noise amplifier 120 within the silicon layer 102. These legacy implementations result in routing a wideband modulated signal off chip, which requires wideband and low-loss interfaces between the silicon layer 102 and the layer of III-V (not shown).

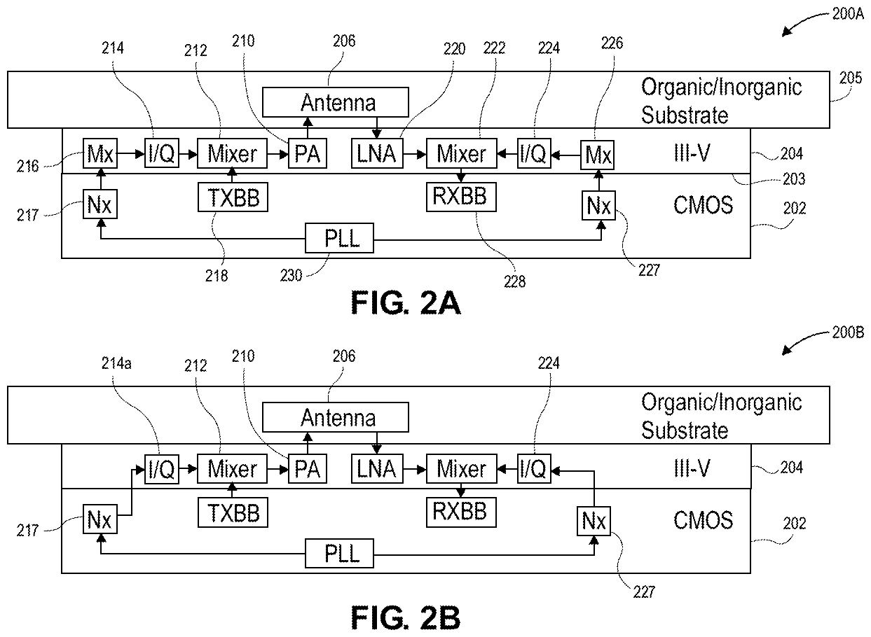

FIGS. 2A-2B illustrate a cross section side view of examples of a sub-terahertz wideband communication package that includes baseband components in a silicon layer and amplifier and mixer components in a III-V layer, in accordance with various embodiments.

FIG. 2A shows a package 200A, which may also be referred to as a transceiver, and which may be similar to package 100 of FIG. 1. Package 200A may include a power amplifier 210, a first mixer 212, a first IQ phase generator 214, and a first multiplier 216, which may be similar to power amplifier 110, first mixer 112, first IQ phase generator 114, and first multiplier 116 of FIG. 1. Package 200A may also include low noise amplifier 220, second mixer 222, second IQ phase generator 224, and second multiplier 226, which may be similar to low noise amplifier 120, second mixer 122, second IQ generator 124, and second multiplier 126 of FIG. 1.

However, unlike package 100 of FIG. 1, the power amplifier 210 and the first mixer 212, and/or the low noise amplifier 220 and the second mixer 222, may be within a layer of III-V material 204. In embodiments, the layer of III-V material 204 may be part of a chip or a die, and in embodiments may be layer transferred on top of a die or a wafer. In embodiments, the layer of III-V material 204 may be on the silicon layer 202, which may be similar to silicon layer 102 of FIG. 1. In embodiments, the first IQ phase generator 214 and/or the multiplier 216 may also be in the layer of III-V material 204. In embodiments, the second IQ phase generator 224 and the second multiplier 226 may be in the layer of III-V material 204.

In embodiments, the silicon layer 202, which may also be referred to as a CMOS layer, may include the TXBB 218, which may be similar to TXBB 118 of FIG. 1, may be coupled with the first mixer 212. In embodiments, the RXBB 228, which may be similar to RXBB 128 of FIG. 1, may be within the silicon layer 202 and coupled with the second mixer 222. In embodiments, there may be a third multiplier 217 within the silicon layer 202 that may be coupled with the first multiplier 216 that is within the layer of III-V material. In embodiments, there may be a fourth multiplier 227 within the silicon layer 202 that may be coupled with the second multiplier 226 that is within the layer of III-V material. In embodiments, a PLL 230, which may be similar to PLL 130 of FIG. 1, may couple the third multiplier 217 with the fourth multiplier 227.

In embodiments, the choice of the various components and their location either in silicon layer 202 or in the layer of III-V material 204 may be chosen for optimal efficiency for each layer. In embodiments, the PLL 230 and frequency synthesis, along with the third multiplier 217 and the fourth multiplier 227, which may be used to multiply a local oscillator signal, may be efficiently implemented within the silicon layer. These embodiments within the silicon layer 202 may provide for high performance and low noise implementations of PLL 230, that may have a lower power consumption, wider frequency tuning range, and lower phase noise.

In embodiments, the TXBB 218 and the RXBB 228 may be placed within the silicon layer 202 with their respective outputs and/or inputs to and/or from the mixers 212, 222 passing across the boundary 203 between the silicon layer 202 in the layer of III-V material 204. In embodiments, this approach leverages a high energy efficiency of CMOS-based process for analog baseband processing, and also allows the architectures of the TXBB 218 and the RXBB 228 to allow higher performance as CMOS is scaled to deeper nodes. In addition this architecture may allow an increase in complexity in the TXBB 218 and RXBB 228 at a lower cost due to scaling, and also yield higher data speeds.

In addition, in embodiments, passing a baseband signal from the TXBB 218 and the RXBB 228 across the boundary 203 and to the mixers of 212, 222 within the layer of III-V material 204 may provide higher bandwidths and lower losses for the interconnects more readily at a baseband frequency rather than at radio frequency. In addition, embodiments may improve bandwidth as compared to legacy implementations due to cutting the boundary as a low impedance node, thus the resulting off chip interface may handle a wider modulation bandwidth more readily than a radiofrequency interface. In addition, lower losses and higher output power, in comparison with legacy implementations, may also be achieved.

Also, in embodiments, placing the mixers 212, 222 within the layer of III-V material 204 also allows the local oscillator multiplication and division through the multipliers 216, 226 to be completed within the layer of III-V material 204. In embodiments, within the layer of III-V material 204, a single phase local oscillator signal from the silicon layer 202 may be further multiplied to a final carrier frequency, and then distributed to the mixer 212, 222. In embodiments, there may be an optional quadrature generation through the IQ phase generators 214, 224, depending upon the transceiver architecture of package 200A, to facilitate up/down conversion of a baseband signal to the carrier frequency. In embodiments, the output of the mixers 212, 222 may then be passed to the amplifiers 210, 220.

In embodiments, implementing the power amplifier 210 and the low noise amplifier 220 within the layer of III-V material 204 may result in greater efficiency, greater output power, and reduced noise when operating at a sub-terahertz frequency. In some embodiments, due to higher density and higher interconnect options available for devices within the silicon layer 202, fabricating some components, for example PLL 230, within the silicon layer 202, may result in greater area efficiency (e.g. smaller size) and greater power efficiency.

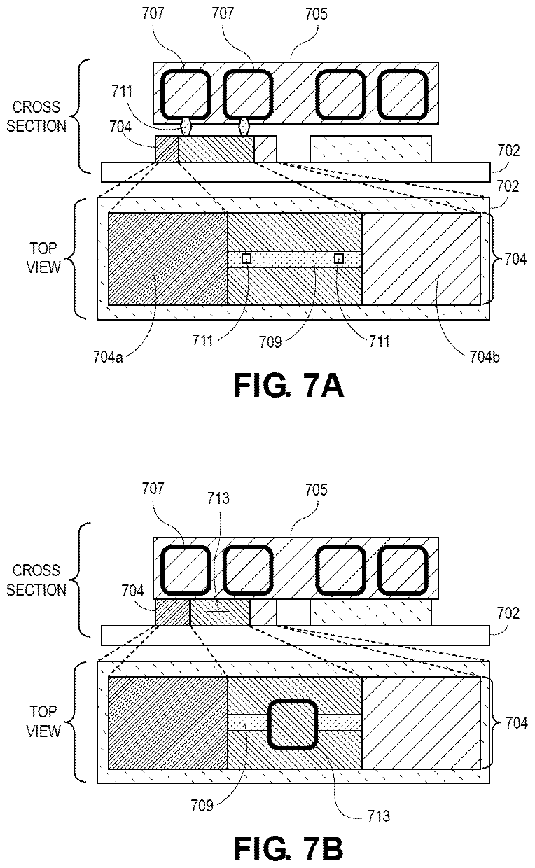

In embodiments, the power amplifier 210 and/or the low noise amplifier 220 may be coupled with the antenna 206. In embodiments, the antenna 206 may be implemented on a substrate 205 that may be chosen for sub-terahertz performance, and material used for the antenna 206 may be selected for low loss at sub-terahertz frequencies. In embodiments, this coupling may be a wide bandwidth coupling in order to preserve the integrity of the modulated signal. As discussed further below with respect to FIGS. 7A-7B, in embodiments either wireless, for example near field coupling, capacitive coupling, resonating electromagnetic structures or the like, and/or wired coupling structures may be used. In embodiments, a traditional conductive connection utilizing a controlled impedance connection, such as a transmission line, may also be used for the coupling, utilizing a micro-bump, a thru substrate via, direct copper to copper bonded pads or the like.

In embodiments, higher carrier frequencies may be accommodated through the higher modulation bandwidth provided by the layer of III-V material 204, which accommodates higher voltages and higher speeds in comparison to silicon.

FIG. 2B shows package 200B, which may be similar to package 200A of FIG. 2A.

Package 200B shows an embodiment where the third multiplier 217 in the silicon layer 202 is coupled with the IQ phase generator 214a within the layer of III-V material 204. Note that in embodiments, the first multiplier 216 and the second multiplier 226 that are within the layer of III-V material 204 of FIG. 2A are not used. Note that in other embodiments, the first IQ phase generator 214a may be located within the silicon layer 202 (not shown).

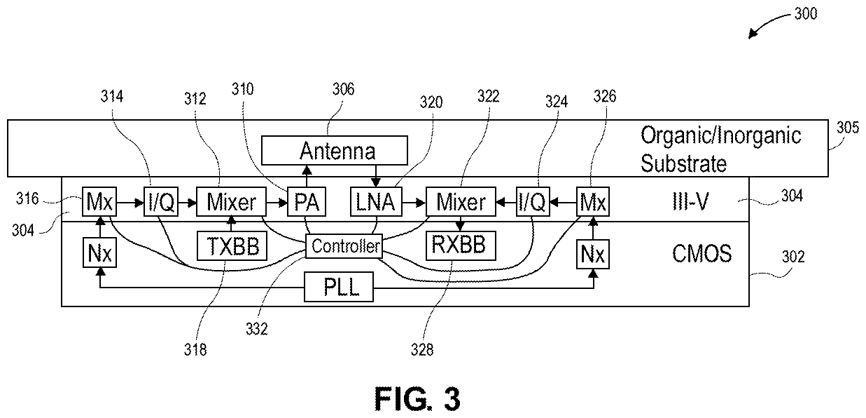

FIG. 3 illustrates a cross-section side view of an example of a sub-terahertz wideband communication package that includes a controller in a silicon layer that is coupled with one or more wideband communication components in a III-V layer on the silicon layer, in accordance with various embodiments. Package 300, which may be similar to package 200A of FIG. 2A, includes an antenna 306 within a substrate 305, where the antenna 306 is coupled with a power amplifier 310 and a low noise amplifier 320 that may be in a layer of III-V material 304. In embodiments, the power amplifier 310 may be coupled with a first mixer 312, a first IQ phase generator 314, and a first multiplier 316. In embodiments, the low noise amplifier 320 may be coupled with the second mixer 322, a second IQ phase generator 324, and a second multiplier 326.

The layer of III-V material 304 may be on a silicon layer 302, which may be referred to as a CMOS layer. The silicon layer 302 may include a TXBB 318 that may be coupled with the first mixer 312 and a RXBB 328 that may be coupled with the second mixer 322. In embodiments, a controller 332 may be formed within the silicon layer 302, and may be electrically coupled with the first multiplier 316, the first IQ phase generator 314, the first mixer 312, the power amplifier 310, the low noise amplifier 320, the second mixer 322, the second IQ phase generator 324, and/or the second multiplier 326.

In embodiments, the controller 332 may be used to control the power amplifier 310, for example, by tuning the output power, tuning the impedance, or tuning the bandwidth of the power amplifier 310. In embodiments, the controller 332 may control the calibration of the first IQ phase generator 314 or the second IQ phase generator 324 to achieve a good phase balance between in-phase (I) and quadrature (Q) routing paths, which in embodiments may be preferred to be 90 degrees, or to minimize amplitude imbalance. In embodiments, the controller 332 may be used to control the antenna 306 by varying the impedance or to perform impedance tuning for the antenna 306 by varying the way signals are radiated. In some embodiments, the controller 332 may serve as a phantom IQ phase generator within the silicon layer 302.

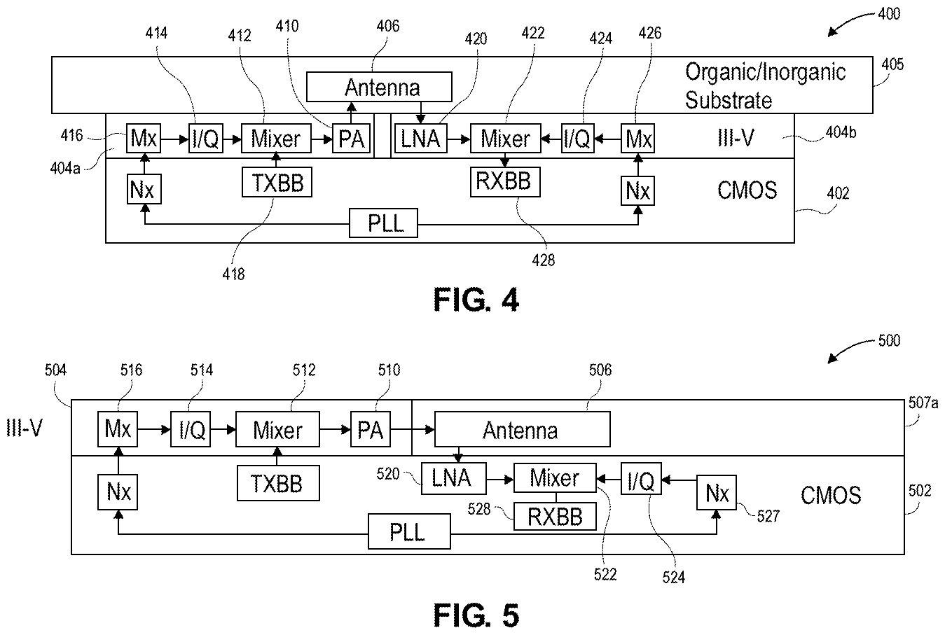

FIG. 4 illustrates a cross-section side view of an example of a sub-terahertz wideband communication package that includes two chips that include a III-V layer on a silicon layer, where one chip is a transmitter and the other chip is a receiver, in accordance with various embodiments. Package 400, which may be similar to package 300 of FIG. 3, includes a silicon layer 402, which may be similar to silicon layer 302 of FIG. 3. Transmitter chip 404a and receiver chip 404b, which both may be similar to a portion of the layer of III-V material 304 of FIG. 3, may be on the silicon layer 402. In embodiments, the transmitter chip 404a and the receiver chip 404b may be individual and separate chips.

In embodiments, the first multiplier 416, first IQ phase generator 414, the first mixer 412, and/or the power amplifier 410 may be in the transmitter chip 404a, and the second multiplier 426, second IQ phase generator 424, second mixer 422 and low noise amplifier 420 may be in the receiver chip 404b. In embodiments, the antenna 406, which may be within a substrate 405, may be on and be communicatively coupled with the transmitter chip 404a and/or the receiver chip 404b. In embodiments, the TXBB 418 and the RXBB 428 may be within the silicon layer 402, and may be respectively coupled with the first mixer 412 and with the second mixer 422. In embodiments, the transmitter chip 404a and the receiver chip 404b may include substrates that include different III-V materials.

FIG. 5 illustrates a cross-section side view of an example of a sub-terahertz wideband communication package that includes a chip that includes a III-V layer that includes a transmitter that is on a silicon layer that includes a receiver, in accordance with various embodiments. Package 500, which may be similar to package 400 of FIG. 4, includes a silicon layer 502, which may be similar to silicon layer 402 of FIG. 4. In embodiments, the silicon layer 502, which may be referred to as a CMOS layer, may include receiver components that may include a low noise amplifier 520, a second mixer 522, a second IQ phase generator 524, and a third multiplier 527. An RXBB 528 may also be within the silicon layer 502 and coupled with the second mixer 522.

In embodiments, a layer of III-V material 504, which may be in the form of a chip, may be on the silicon layer 502 and may include transmitter components, that may include a first multiplier 516 that is coupled with a first IQ phase generator 514, which in turn is coupled with the first mixer 512. The first mixer 512 may be coupled with a power amplifier 510. In embodiments, a layer 507a may be on the silicon layer 502 and may include an antenna 506. In embodiments, the layer 507a may be a chip. In embodiments, the layer 507a that includes the antenna 506 may be layer transferred onto a top of the silicon layer 502 or may be layer transferred onto a top of the layer of III-V material 504. In embodiments, a thickness of the antenna 506 or of the layer 507a does not have to be the same as a thickness of the layer of III-V material 504 or the silicon layer 502.

In embodiments, the layer 507a may be coupled with the layer of III-V material 504, where the power amplifier 510 is coupled with the antenna 506. In embodiments, this coupling may either be a wireless coupling or a conductive coupling such as a metal wire coupling. In embodiments, the low noise amplifier 520 may also be coupled with the antenna 506. It should be appreciated that although in this embodiment the receiver components are within the silicon layer 502 and the transmitter components are within the layer of III-V material 504, in other embodiments the transmitter components may be within the silicon layer 502 and the receiver components may be within the layer of III-V material 504. In embodiments, the antenna 506 may be implemented within a III-V layer of material (not shown).

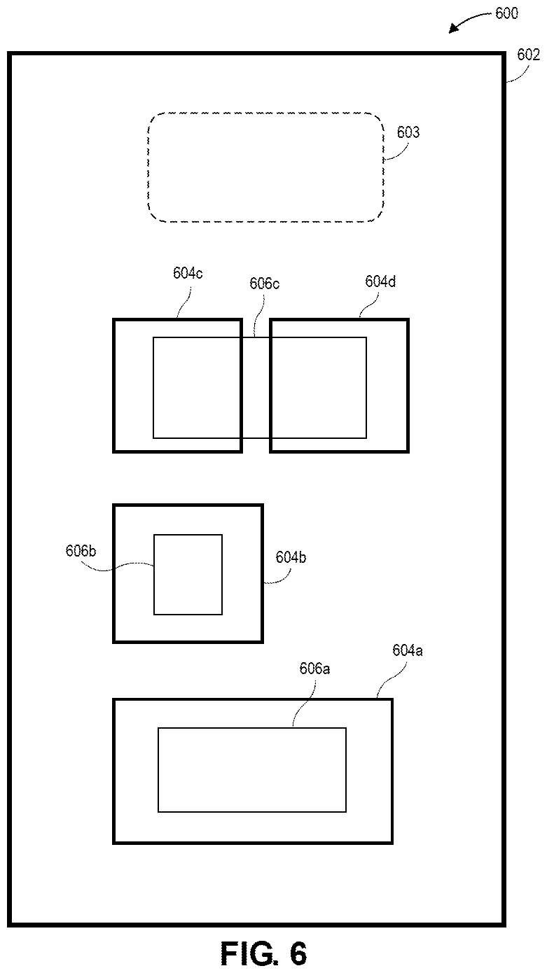

FIG. 6 illustrates a top-down view of an example of a silicon layer with various chips on the silicon layer that include a III-V layer with sub-terahertz wideband communication components, in accordance with various embodiments. Package 600 shows a top-down view that includes a silicon layer 602, which may be similar to silicon layer 402 of FIG. 4. In embodiments, a computer/processor area 603 within the silicon layer 602 may include processor and/or compute circuitry that may be electrically coupled with transmitter receive baseband components, for example TXBB 418 and/or RXBB 428 of FIG. 4.

In embodiments, a layer of III-V material 604a, which may be similar to layer of III-V material 204 of FIG. 2A, may be on the silicon layer 602. In embodiments, the layer of III-V material 604a may include both transmit and receive components as described with respect to FIG. 2A. In embodiments, the layer of III-V material 604a may be in the form of a chip or a die. In embodiments, an antenna 606a, which may be similar to antenna 406 of FIG. 4, may be on top and communicatively coupled with the layer of III-V material 604a.

In embodiments, a layer of III-V material 604b, which may be similar to layer of III-V material 504 of FIG. 5, may be on the silicon layer 602. In embodiments, the layer of III-V material 604b may include transmitter components with receiver components being within the silicon layer 602, similar to the embodiments described with respect to FIG. 5. In embodiments, an antenna 606b, which may be similar to antenna 606a, may be communicatively coupled with the layer of III-V material 604b and may be communicatively coupled with the silicon layer 602.

In embodiments, a first chip 604c that includes a layer of III-V material, which may include transmitter components that may be similar to the components within transmitter chip 404a of FIG. 4, may be on the silicon layer 602. In embodiments, a second chip 604d that includes a layer of III-V material, may be on the silicon layer 602 and may be proximate to the first chip 604c. In embodiments, the layer of III-V material in the second chip 604d may include receiver components, which may be similar to receiver chip 404b of FIG. 4. In embodiments, antenna 606c may be on the first chip 604c and the second chip 604d. In embodiments, the antenna 606c may be layer transferred onto the silicon layer 602.

FIGS. 7A-7B illustrate top-down views and cross-section side views of wired and wireless communications between a chip that includes a III-V layer of a sub-terahertz wideband communication package and an antenna, in accordance with various embodiments. FIG. 7A shows a top-down view that includes a silicon layer 702 and a layer of III-V material 704 that includes a transmitter portion 704a and a receiver portion 704b. In embodiments, the silicon layer 702 may be similar to silicon layer 202 of FIG. 2A. In embodiments, the transmitter portion 704a may include components that may be similar to the first multiplier 216, the first IQ phase generator 214, the first mixer 212, and the power amplifier 210 of FIG. 2A. In embodiments, the receiver portion 704b may include components that may be similar to the second multiplier 226, the second IQ phase generator 224, the second mixer 222, and the low noise amplifier 220 of FIG. 2A.

The cross-section shows antennas 707 within a substrate 705, which may be similar to antenna 206 and substrate 205 of FIG. 2A. In embodiments, an electrical connector 709 may be between the transmitter portion 704a and the receiver portion 704b. In embodiments, a wire 711 may directly physically and electrically couple the antennas 707 with the electrical connector 709. In embodiments, the wire 711 may be some other metallic or electrically conductive material. In this way, the antennas 707 may be directly physically and electrically coupled with the components within the layer of III-V material 704.

FIG. 7B, which may be similar to FIG. 7A, except that wireless component 713 may be electrically coupled with the electrical device 709 that may wirelessly communicate with the antennas 707. Such devices include capacitively-coupled structures, for example a patch or a slot, near field coupled structures, cavity resonators or other resonating elements.

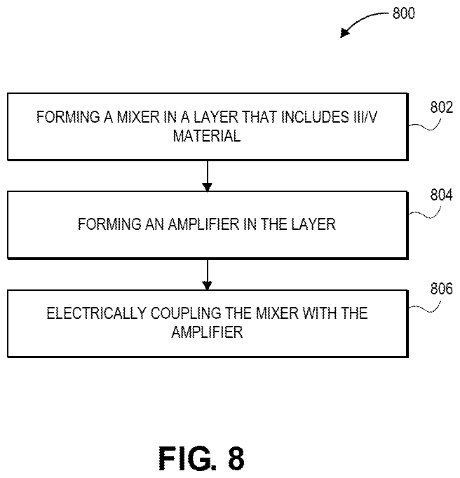

FIG. 8 illustrates an example of a process for manufacturing a sub-terahertz wideband communication package that is at least partially formed within a III-V layer, in accordance with various embodiments. In embodiments, the process 800 may be implemented using the techniques, apparatus, systems, and/or processes described herein, and in particular with respect to FIGS. 2A-7B.

At block 802, the process may include forming a mixer in a layer that includes III/V material. In embodiments, the mixer may be similar to first mixer 212 or to second mixer 222 of FIGS. 2A-2B, first mixer 312 or second mixer 322 of FIG. 3, first mixer 412 or second mixer 422 of FIG. 4, or first mixer 512 FIG. 5.

At block 804, the process may further include forming an amplifier in the layer. In embodiments, the amplifier may be similar to power amplifier 210 or low noise amplifier 220 of FIGS. 2A-2B, power amplifier 310 or low noise amplifier 320 of FIG. 3, power amplifier 410 or low noise amplifier 420 of FIG. 4, or power amplifier 510 of FIG. 5.

At block 806, the process may further include electrically coupling the mixer with the amplifier.

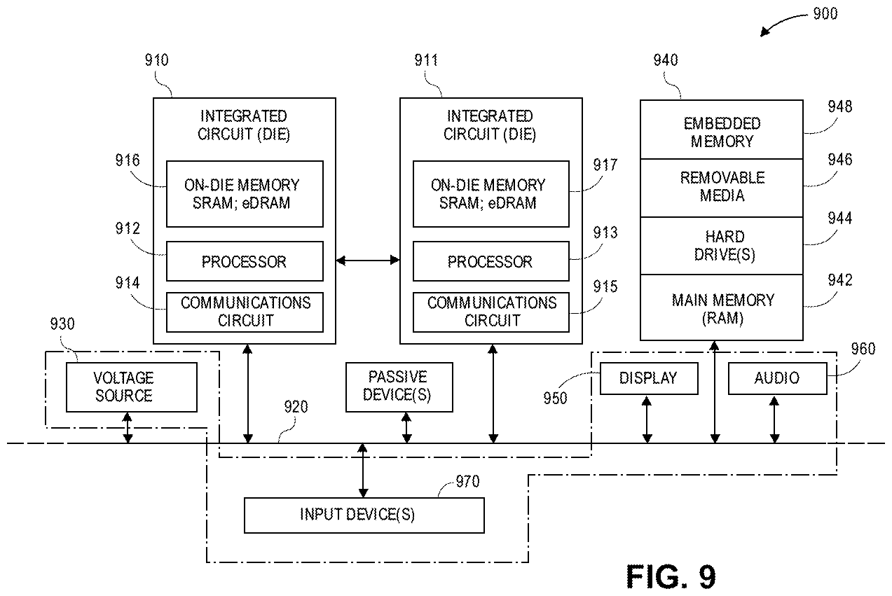

FIG. 9 is a schematic of a computer system 900, in accordance with an embodiment of the present invention. The computer system 900 (also referred to as the electronic system 900) as depicted can embody an amplifier and mixer in a III-V material for wideband sub-terahertz communication, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, an amplifier and mixer in a III-V material for wideband sub-terahertz communication, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including a package substrate having an amplifier and mixer in a III-V material for wideband sub-terahertz communication, according to any of the several disclosed embodiments and their equivalents, an electronic system, a computer system, one or more methods of fabricating an integrated circuit, and one or more methods of fabricating an electronic assembly that includes a package substrate having an amplifier and mixer in a III-V material for wideband sub-terahertz communication, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having an amplifier and mixer in a III-V material for wideband sub-terahertz communication embodiments and their equivalents. A foundation substrate may be included, as represented by the dashed line of FIG. 9. Passive devices may also be included, as is also depicted in FIG. 9.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### Examples

The following paragraphs describe examples of various embodiments.

Example 1 is an apparatus comprising: a layer that includes III-V material; a mixer in the layer; and an amplifier in the layer, wherein the mixer and the amplifier are electrically coupled with each other.

Example 2 includes the apparatus of example 1, wherein the amplifier is a selected one of: a low noise amplifier or a power amplifier.

Example 3 includes the apparatus of examples 1 or 2, further comprising an IQ phase generator in the layer, wherein the IQ phase generator and the mixer are electrically coupled with each other.

Example 4 includes the apparatus of example 3, further comprising a frequency multiplier in the layer, wherein the multiplier and the IQ phase generator are electrically coupled with each other.

Example 5 includes the apparatus of examples 1, 2, 3, or 4, wherein the mixer is a first mixer, wherein the amplifier is a first amplifier, and wherein the first amplifier is a power amplifier; and further comprising: a second mixer in the layer; and a second amplifier in the layer, wherein the second amplifier is a low noise amplifier, and wherein the second mixer and the second amplifier are electrically coupled with each other.

Example 6 includes the apparatus of examples 1, 2, 3, 4, or 5, wherein the amplifier is electrically coupled with an antenna.

Example 7 includes the apparatus of examples 1, 2, 3, 4, 5, or 6, wherein the layer is within a selected one of: a chip or a die.

Example 8 is a system for wideband communication, the system comprising: a first layer that includes III/V material; a mixer in the first layer; an amplifier in the first layer, wherein the amplifier and the mixer are electrically coupled with each other; a second layer that includes silicon; and a baseband circuitry in the second layer, wherein the baseband circuitry is electrically coupled with the mixer.

Example 9 includes the system of example 8, wherein the amplifier is a selected one of: a power amplifier or a low noise amplifier, and wherein the baseband circuitry is a selected one of: transmitter baseband circuitry or receiver baseband circuitry.

Example 10 includes the system of examples 8 or 9, wherein the first layer is on the second layer.

Example 11 includes the system of examples 8, 9, 10, or 11, further comprising a third layer, wherein the third layer includes one or more antennas, and wherein the one or more antennas are communicatively coupled with the amplifier.

Example 12 includes the system of example 11, wherein the one or more antennas are directly electrically coupled with the amplifier.

Example 13 includes the system of examples 8, 9, 10, 11, or 12, further comprising a IQ phase generator in the first layer, wherein the IQ phase generator is electrically coupled with the mixer.

Example 14 includes the system of example 13, further comprising a frequency multiplier in the first layer, wherein the multiplier is electrically coupled with the IQ phase generator.

Example 15 includes the system of examples 13 or 14, further comprising a controller in the second layer, wherein the controller is electrically coupled with the IQ phase generator in the first layer.

Example 16 includes the system of examples 8, 9, 10, 11, 12, 13, 14, or 15, further comprising a controller in the second layer, wherein the controller is electrically coupled with the amplifier.

Example 17 includes the system of examples 8, 9, 10, 11, 12, 13, 14, 15, or 16, further comprising at least a portion of a processor in the second layer.

Example 18 is a method comprising: forming a mixer in a layer that includes III/V material; forming an amplifier in the layer; and electrically coupling the mixer with the amplifier.

Example 19 includes the method of example 18, wherein the layer is a first layer; and further comprising: forming baseband circuitry in a second layer, wherein the second layer includes silicon; and electrically coupling the baseband circuitry with the mixer.

Example 20 includes the method of examples 18 or 19, further comprising: forming an IQ phase generator in the layer; and electrically coupling the IQ phase generator with the mixer.

What is claimed is:

1. An apparatus comprising:
a layer that includes III-V material;
a mixer in the layer; and
an amplifier in the layer, wherein the mixer and the amplifier are electrically coupled with each other.

2. The apparatus of claim 1, wherein the amplifier is a selected one of: a low noise amplifier or a power amplifier.

3. The apparatus of claim 1, further comprising an IQ phase generator in the layer, wherein the IQ phase generator and the mixer are electrically coupled with each other.

4. The apparatus of claim 3, further comprising a frequency multiplier in the layer, wherein the multiplier and the IQ phase generator are electrically coupled with each other.

5. The apparatus of claim 1, wherein the mixer is a first mixer, wherein the amplifier is a first amplifier, and wherein the first amplifier is a power amplifier; and further comprising:
a second mixer in the layer; and
a second amplifier in the layer, wherein the second amplifier is a low noise amplifier, and wherein the second mixer and the second amplifier are electrically coupled with each other.

6. The apparatus of claim 1, wherein the amplifier is electrically coupled with an antenna.

7. The apparatus of claim 1, wherein the layer is within a selected one of: a chip or a die.

8. A system for wideband communication, the system comprising:
a first layer that includes III/V material;
a mixer in the first layer;
an amplifier in the first layer, wherein the amplifier and the mixer are electrically coupled with each other;
a second layer that includes silicon; and
a baseband circuitry in the second layer, wherein the baseband circuitry is electrically coupled with the mixer.

9. The system of claim 8, wherein the amplifier is a selected one of: a power amplifier or a low noise amplifier, and wherein the baseband circuitry is a selected one of: transmitter baseband circuitry or receiver baseband circuitry.

10. The system of claim 8, wherein the first layer is on the second layer.

11. The system of claim 8, further comprising a third layer, wherein the third layer includes one or more antennas, and wherein the one or more antennas are communicatively coupled with the amplifier.

12. The system of claim 11, wherein the one or more antennas are directly electrically coupled with the amplifier.

13. The system of claim 8, further comprising a IQ phase generator in the first layer, wherein the IQ phase generator is electrically coupled with the mixer.

14. The system of claim 13, further comprising a frequency multiplier in the first layer, wherein the multiplier is electrically coupled with the IQ phase generator.

15. The system of claim 13, further comprising a controller in the second layer, wherein the controller is electrically coupled with the IQ phase generator in the first layer.

16. The system of claim 8, further comprising a controller in the second layer, wherein the controller is electrically coupled with the amplifier.

17. The system of claim 8, further comprising at least a portion of a processor in the second layer.

18. A method comprising:
forming a mixer in a layer that includes III/V material;
forming an amplifier in the layer; and
electrically coupling the mixer with the amplifier.

19. The method of claim 18, wherein the layer is a first layer, and further comprising:
forming baseband circuitry in a second layer, wherein the second layer includes silicon; and
electrically coupling the baseband circuitry with the mixer.

20. The method of claim 18, further comprising:
forming an IQ phase generator in the layer; and
electrically coupling the IQ phase generator with the mixer.
